(19) United States
(12) Patent Application Publication
(10) Pub. No.: US 2008/0142721 A1
(43) Pub. Date: Jun. 19, 2008

(54) X-Ray Detector

(75) Inventor: Martin Spahn, Chicago, IL (US)

Correspondence Address: SCHIFF HARDIN, LLP;PATENT DEPARTMENT, 6600 SEARS TOWER, CHICAGO, IL, 60606-6473, US

(73) Assignee: SIEMENS AKTIENGESELLSCHAFT, Munchen (DE)

(21) Appl. No.: 11/628,274

(22) PCT Filed: May 30, 2005
(86) PCT No.: PCT/EP05/52458

§ 371 Date: Jun. 14, 2007

(30) Foreign Application Priority Data
Jun. 1, 2004 (DE) 10 2004 026 618.2

(51) Int. Cl. G01T 1/20

(52) U.S. Cl. 250/370.11

(57) ABSTRACT

An x-ray detector is provided comprising a converter layer converting x-ray radiation into light. An array is provided for detection of the light uncoupled from the converter layer. The photodiodes are produced from an organic semiconductor material and surrounded by a casing substantially impermeable to substances reacting with the semiconductor material.

### BACKGROUND

The disclosure concerns an x-ray detector with a converter layer.

Such an x-ray detector is, for example, known from “Flachbilddetektoren in der Röntgendiagnostik” by M. Spahn et al., Radiologie 2003, vol. 43, pages 340-350. The known x-ray detector comprises an array of photodiodes produced from amorphous silicon. A disadvantage of these x-ray detectors is that the production of photodiodes on the basis of silicon is elaborate and expensive.

Photodiodes produced from organic semiconductor materials are, for example, known from “Plastic Solar Cells” by Christoph J. Brabec et al., Adv. Funct. Matter [sic], 2001, 11, Nr. 1, pages 15 through 26.

### SUMMARY

It is an object to remedy the disadvantages according to the prior art. In particular an x-ray detector should be specified which can be produced simply and cost-effectively.

An x-ray detector is provided comprising a converter layer converting x-ray radiation into light. An array is provided for detection of the light uncoupled from the converter layer. The photodiodes are produced from an organic semiconductor material and surrounded by a casing substantially impermeable to substances reacting with the semiconductor material.

### BRIEF DESCRIPTION OF THE DRAWINGS

FIG. 1 is a sectional view of an x-ray detector;

FIG. 2 is a first sectional view of an array formed from organic photodiodes;

FIG. 3 is a second sectional view of an array formed from organic photodiodes;

FIG. 4 is a third sectional view of an array formed from organic photodiodes;

FIG. 5 is a fourth sectional view of an array formed from organic photodiodes;

FIG. 6 is a fifth sectional view of an array formed from organic photodiodes; and

FIG. 7 is a sixth sectional view of an array formed from organic photodiodes.

### DESCRIPTION OF THE PREFERRED EMBODIMENT

For the purposes of promoting an understanding of the principles of the invention, reference will now be made to the preferred embodiment illustrated in the drawings and specific language will be used to describe the same. It will nevertheless be understood that no limitation of the scope of the invention is thereby intended, such alterations and further modifications in the illustrated device, and/or method, and such further applications of the principles of the invention as illustrated therein being contemplated as would normally occur now or in the future to one skilled in the art to which the invention relates.

According to the preferred embodiment it is provided that the photodiodes are produced from an organic semiconductor material and are surrounded by a casing that is essentially impermeable for substances reacting with the semiconductor material. Photodiodes made from an organic semiconductor material can be applied on a substrate in a particularly simple manner, for example with a printing method. The photodiodes are surrounded by an impermeable casing for protection, for example against the penetration of moisture or other substances reacting with the semiconductor material. Such an x-ray detector can be produced simply and cost-effectively.

The casing can comprise a layer that is chemically inert with regard to the semiconductor material. By “chemically inert” what is understood is that, given a contact with the semiconductor material, the layer does not change this, such that the function of the photodiode is substantially impaired. The layer is furthermore substantially impermeable for substances which react with the semiconductor material. By the term “react” what is understood is that the function of the photodiodes is not significantly influenced by a reaction of the substance with the semiconductor material. The semiconductor material can be protected from external influences and the lifespan of the photodiodes can be increased with such a casing.

According to one embodiment, the semiconductor material is stable up to a temperature of 150° C. In the manufacturing it is thus possible to implement a tempering with temperatures up to 150° C. before the closing of the casing. A residual moisture remaining in the course of the manufacturing can be removed via the tempering. The function and lifespan of the photodiodes can thus be improved, in particular given hygroscopic semiconductor materials.

According to a further embodiment the casing is produced from a glass, an inorganic oxide, a plastic, a silicon compound or a combination of these. Glass is chemically inert and impermeable with regard to a plurality of substances. Due to the rigidity of glass, the photodetectors can be sufficiently protected from mechanical damage. Furthermore, glass is transparent for light. The light uncoupled from the converter layer can penetrate the casing substantially without losses. The degree of efficiency of the x-ray detector can be improved.

With a suitably selected plastic it is possible to produce a flexible casing with sufficient rigidity. The casing can be adapted to the shape of the array formed from photodiodes. At the same time a sufficient (for example mechanical) protection can be achieved. With a plastic particularly thin casings can be produced which exhibit an excellent transparency. A scattering of the light caused by the casing can therewith be nearly precluded.

The casing can, for example, also comprise a combination of glass and plastic. The advantages of a casing made from glass and one made from plastic can thereby be combined. Glass can, for example, be used as a substrate. The rigidity of glass enables a sufficient protection from mechanical stresses. The surface of the photodiodes not covered by the substrate can be covered with a plastic layer and, for example, can be attached on the substrate with an adhesive. If the plastic layer is applied on the converter layer, it is advantageous to apply an optimally thin plastic layer on the photodiodes. Absorption and scatter losses are thus reduced. The degree of efficiency of the x-ray detector can be improved.

It has proven to be advantageous to use aluminum oxide as an inorganic oxide. The plastic can be polyethyleneterephtalate, polyethylenenaphtalate or polyparaxylylene. The silicon compound can be formed from SiO₂ or SiNₓ. The aforementioned materials are chemically inert with regard to organic semiconductor materials. They can even be produced in sufficiently sealed thin layer thickness such that organic semiconductor materials are thus effectively protected from the penetration of, for example, moisture. Apart from this, the aforementioned materials exhibit similar thermal coefficients of expansion. A casing produced from a combination of the aforementioned materials is particularly stable.

The casing can comprise a region formed from a plurality of plies arranged one atop the other. For example, the substrate can thus be a component of the casing. An array mounted on the substrate can be covered by a layer formed from a plurality of plies, which layer is connected in a sealed manner on all sides with the substrate.

According to a further embodiment, the casing exhibits a region with a thickness of approximately 1 μm to 5 μm. For the semiconductor material a sufficient protection from external influences can be achieved with such a thickness (for example of the plastic). Furthermore, absorption and scattering of the light uncoupled from the converter layer can be significantly reduced via a reduced thickness, at least in the region of the entrance of the light into the casing. The degree of efficiency as well as the function of the x-ray detector can thus be improved.

According to a further embodiment, the casing comprises a glass fiber optic. The scattering of the light (uncoupled from the converter layer) in the casing can be significantly reduced with the glass fiber optic. The degree of efficiency and the resolution of the x-ray detector can be improved.

According to a further embodiment, an absorber material which absorbs substances reacting with the semiconductor material is arranged in or outside of the casing. The semiconductor material can be protected with the absorber material. For example, after the production of the x-ray detector substances can be absorbed which, together with the semiconductor material, are surrounded by the casing. Furthermore the semiconductor material can be protected from substances which penetrate the casing. A possible cause for this can, for example, be a mechanical damage of the casing. The permeability can also be altered via an aging of the casing or of seals. The lifespan of the x-ray detector can be increased with the absorber material and the function of the x-ray detector can be temporally stabilized.

Furthermore it is possible with an absorber material to implement the manufacturing of the array formed from photodiodes under less strict purity conditions. In the manufacturing remaining residual quantities of substances reacting with the semiconductor material (for example moisture) can be bound by the absorber material after the event. The manufacturing of the x-ray detector can be implemented more simply and cost-effectively.

According to an appropriate embodiment the casing is accommodated in a housing in which the absorber material is arranged outside the casing. In this embodiment the inorganic semiconductor material is protected particularly well, namely by the casing, the housing and the absorber material. Given a leakiness of the housing, unwanted, penetrating substances (in particular moisture) are initially absorbed by the absorber material.

The absorber material can be a metal (advantageously potassium or barium), advantageously metal oxide formed from K₂O or BaO. Alternatively the absorber material can be a silicate (advantageously a ceolite [sic]). The absorber materials enable an efficient protection of organic semiconductor materials from residual moisture or penetrating moisture. With an absorber material it is possible to increase the lifespan of the x-ray detector and to improve its function.

The x-ray detector of FIG. 1 comprises the following layers in the direction R of an incident x-ray radiation: a first substrate 1, a converter layer 2, a first layer 3, a bonding layer 4, a second layer 5, an array 7 formed from a plurality of photodiodes 6 and a second substrate 8. A bonding agent is designated with the reference character 9. The bonding agent can be a permanently elastic sealing material, for example silicon or the like.

The converter layer 2 is mounted on the first substrate 1. The converter layer 2 converts an incident x-ray radiation S into light L. The converter layer 2 is covered with a first layer 3 for protection from external influences. The photodiodes 6 are produced from an organic semiconductor material. The production of photodiodes on the basis of semiconductor polymers is, for example, known from “Plastic Solar Cells” by Christoph J. Brabec et al., Adv. Func. Mater, 2001, 11, Nr. 1, pages 15 through 26. The disclosure content of this document is herewith incorporated. The array 7 formed from the photodiodes 6 is covered with the second layer 5. The second layer 5 and the second substrate 8 are connected with the bonding agent 9. The bonding agent 9 simultaneously serves as a seal between the second substrate 8 and the second layer 5. The second layer 5, the bonding agent 9 and the second substrate 8 are impermeable for substances reacting with the semiconductor material. Photodiodes 6 are thus protected from external influences as well as from a direct contact with the bonding layer 4. The second layer 5 is mounted on the first layer 3 by means of the bonding layer 4. The bonding layer 4 can, for example, be a conventional adhesive layer that, for example, is produced from a synthetic resin, an epoxy resin or the like. The first layer 3, the bonding layer 4 and the second layer 5 are transparent. The light L generated in the converter layer 2 and uncoupled arrives at the photodiodes 6 without significant absorption losses. There the light L is converted into electrical signals. The second layer 5 and the second substrate 8 can, for example, be produced from glass or plastic. The converter layer can be produced from a scintillator material such as, for example, CsJ or Gs₂O₂S. The first substrate 1 can, for example, be produced from glass or aluminum. The first layer 3 can be produced from a transparent material, for example from aluminum oxide.

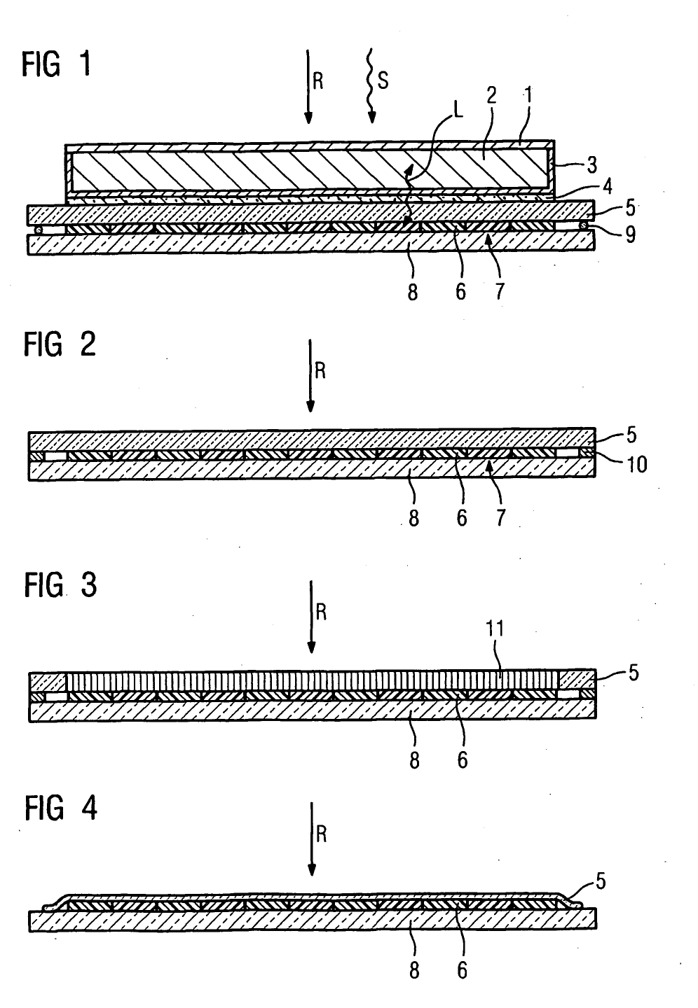

Alternative embodiments are shown in FIG. 2 through FIG. 5. For simplification the converter layer 2, the first substrate 1, the first layer 3 and the bonding layer 4 are not shown. In general the converter layer 2 can be attached with the side of the first substrate 1 or the side of the first layer 3 on the second substrate 8 or on the second layer 5 with the bonding layer 4. The layers between converter layer 2 and the array 7 formed from photodiodes 6 are thus transparent and substantially cause no scattering of the light L. The second substrate 8, the second layer 5 as well as the bonding agent 9 are chemically inert with regard to the semiconductor material. Furthermore they are substantially impermeable for substances reacting with the semiconductor material. They form a casing surrounding the photodiodes 6.

In FIG. 2 the array 7 formed from photodiodes 6 is mounted on the second substrate 8 made from glass or plastic. The array 7 formed from photodiodes 6 is covered with the second layer 5 made from glass or plastic. The bonding agent 9 of FIG. 1 is replaced in FIG. 2 by webs 10 made from glass or plastic at the edges.

In FIG. 3 the second layer 5 comprises a glass fiber optic 11. A scattering in the second layer 5 of the light uncoupled from the converter layer 2 is reduced by means of the glass fiber optic 11.

In FIG. 4 the second layer 5 is a thin layer made from plastic. The thickness of the second layer 5 lies in the range between 1 μm and 5 μm. The second layer 5 is connected at the edges with the second substrate 8. The second layer can be a layer produced from plastic, which layer is advantageously produced from polyparaxylylene. Such layers adhere particularly well to a substrate when this is cleaned before the application of the plastic layer. An alkali cleaner or also plasma etching can thus be used for cleaning. The second layer can, for example, by applied by means of PVD methods.

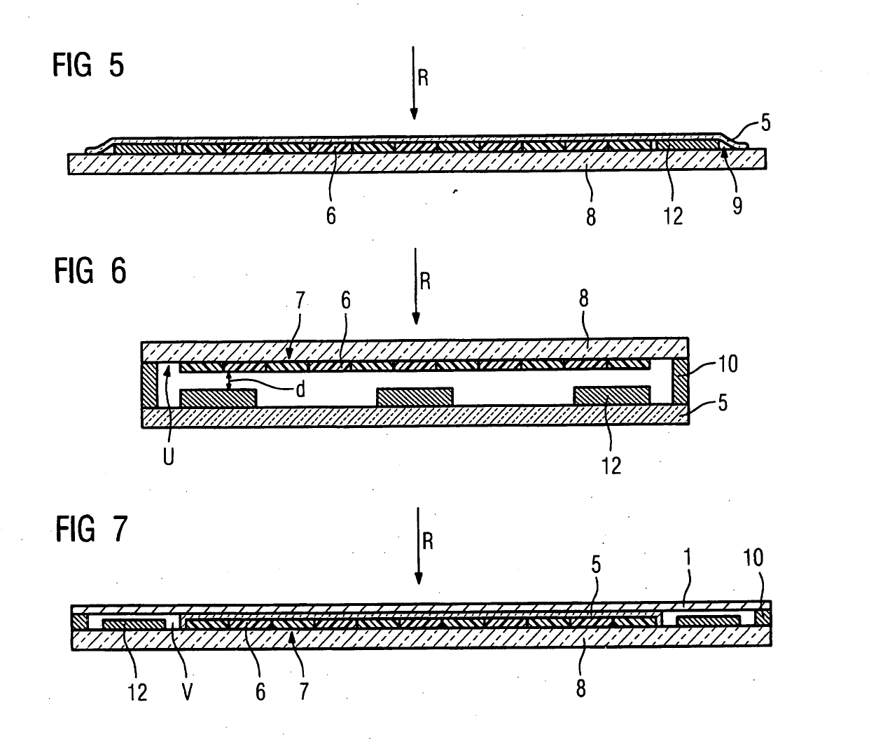

In comparison to FIG. 4, in FIG. 5 an absorber material 12 is located in an envelope formed by the second substrate 8 and the second layer 5. The absorber material 12 serves for absorption of substances reacting with the photodiodes 6. These can thereby be substances which remain in the envelope in the manufacturing process or are let past in the course of time by the second substrate 8, the second layer 5 or the bonding agent 9. For example, metal oxides such as KaO, BaO, or silicates such as ceolite can be used as absorber materials. Humidity can be bound with the absorber materials KaO, BaO, or ceolite.

FIG. 6 shows an alternative application of the absorber material 12 relative to FIG. 5. The absorber material 12 is applied on the second layer 5 and is located in the direction R with a distance d below the photodiodes 6. The second layer 5 is applied with webs 10 on an underside U of the second substrate 8. In comparison to FIG. 6, the absorber material 12 of FIG. 5 is located on average closer to the semiconductor material of the photodiodes 6. The absorption of substances can be improved with the illustrated arrangement of the absorber material 12.

FIG. 7 shows a sixth section view of an array formed from organic photodiodes. The photodiodes 6 are thus surrounded by a casing formed from the second substrate 8 and the second layer 5. The casing is accommodated in a housing which here is formed from the first substrate 1 and the bonding agent (here in the form of the webs 10). A floor of the housing is advantageously formed by the second substrate 8. In the housing the absorber material 12 can be accommodated outside of the casing. The proposed embodiment ensures a particularly secure protection of the photodiodes 6 from penetration of moisture.

While a preferred embodiment has been illustrated and described in detail in the drawings and foregoing description, the same is to be considered as illustrative and not restrictive in character, it being understood that only the preferred embodiment has been shown and described and that all changes and modifications that come within the spirit of the invention both now or in the future are desired to be protected.

1-15. (canceled)

16. An x-ray detector, comprising:
a converter layer converting x-ray radiation into light;
an array of photodiodes for detection of the light uncoupled from the converter layer; and
the photodiodes being produced from an organic semiconductor material and surrounded by a casing substantially impermeable to substances reacting with the semiconductor material.

17. An x-ray detector according to claim 16 wherein the semiconductor material is stable up to a temperature of 150° C.

18. An x-ray detector according to claim 16 wherein the casing is produced from a glass, an inorganic oxide, a plastic, a silicon compound, or a combination of these.

19. An x-ray detector according to claim 18 wherein the inorganic oxide comprises aluminum oxide.

20. An x-ray detector according to claim 18 wherein the plastic comprises a polyethyleneterephtalate, polyethylenenaphtalate, or polyparaxylylene.

21. An x-ray detector according to claim 18 wherein the silicon compound comprises SiO₂ or SiNₓ.

22. An x-ray detector according to claim 16 wherein the casing exhibits a region formed from a plurality of plies arranged atop one another.

23. An x-ray detector according to claim 16 wherein the array is mounted on a substrate and the substrate comprises a component of the casing.

24. An x-ray detector according to claim 16 wherein the casing exhibits a region with a thickness of approximately 1 μm to 5 μm.

25. An x-ray detector according to claim 16 wherein the casing comprises a glass fiber optic.

26. An x-ray detector according to claim 16 wherein an absorber material which absorbs substances reacting with the semiconductor material is arranged in or outside of the casing.

27. An x-ray detector according to claim 26 wherein the casing is accommodated in a housing in which the absorber material is arranged outside of the casing.

28. An x-ray detector according to claim 21 wherein the absorber material is a metal.

29. An x-ray detector according to claim 26 wherein the absorber material is a metal oxide.

30. An x-ray detector according to claim 26 wherein the absorber material comprises a silicate.

31. An x-ray detector according to claim 16 wherein said array is mounted on a substrate.

32. An x-ray detector according to claim 28 wherein said metal comprises potassium or barium.

33. An x-ray detector according to claim 29 wherein the metal oxide comprises K₂O or BaO.

34. An x-ray detector according to claim 30 wherein the silicate comprises a ceolite.

35. An x-ray detector, comprising:
a converter layer converting x-ray radiation into light;
an array mounted on a substrate and formed from a plurality of photodiodes for detection of the light uncoupled from the converter layer; and
the photodiodes being produced from an organic semiconductor material and surrounded by a casing substantially impermeable to substances reacting with the semiconductor material, the substrate being a component of the casing.
